(19) United States
(12) Patent Application Publication
(10) Pub. No.: US 2024/0300011 A1
(43) Pub. Date: Sep. 12, 2024

(54) METAL PARTICLE AS WELL AS PREPARATION METHOD THEREFOR AND USE THEREOF

(71) Applicant: SUZHOU AMART ENTERPRISE MANAGEMENT CO. LTD., Suzhou (CN)

(72) Inventor: Qiang GONG, Suzhou (CN)

(21) Appl. No.: 18/280,666

(22) PCT Filed: Dec. 30, 2022
(86) PCT No.: PCT/CN2022/143759

§ 371 Date: Sep. 6, 2023

(30) Foreign Application Priority Data
Jan. 11, 2022 (CN) 202210024080.9

(51) Int. Cl. B22F 1/065; B22F 1/054; B22F 9/24

(52) U.S. Cl. CPC B22F 1/065; B22F 1/054; B22F 9/24; B22F 2301/255; B22F 2998/10

(57) ABSTRACT

A metal particle, in which holes are distributed at the center, has a high degree of sphericity, a low shrinkage ratio, and small grains therein. In a preparation method for the metal particle, spherical or quasi-spherical metal seed crystals are introduced to prepare a polyol-seed crystal system, so that the metal particle has a controllable particle size and degree of sphericity in a whole reduction process, metal particles in a metal oxide or metal salt solution containing a metal source in the seed crystals can be rapidly and stably reduced, and the shape of formed metal particles is guaranteed to spherical or quasi-spherical; and the particle sizes of the metal particles can be adjusted by means of the number and the sizes of the introduced spherical nano-metal seed crystals. The metal particles are applied to a photovoltaic cell or a semiconductor conducive adhesive.

### TECHNICAL FIELD

The present invention relates to the technical field of metallic materials, in particular to a metal particle as well as a preparation method therefor and use thereof.

### BACKGROUND

A composition containing tiny metal particles or a dispersion thereof can be used in the fields of formation of wiring in flat panel displays (FPDs), solar cells, and radio frequency identification (RFID), buried wiring in fine channels, through holes, etc., coloring materials for painting cars and boats, carriers for adsorbing biochemical substances in the fields of medical treatment, diagnosis, and biotechnology, catalysts, flexible printed circuits, capacitors, and the like. And, with the current and future development of the optoelectronic technology industry, and the development of electronic components in the direction of miniaturization and high performance, higher requirements are put forward for the performance indexes such as sphericity, dispersibility and a particle size of tiny metal nanoparticles.

In the prior art, a method for preparing metal particles includes physical methods including an atomization method, a vapor phase evaporation method, a grinding method and the like, and chemical methods mainly including a sol-gel method, a liquid phase reduction method, physical vapor deposition (PVD), a hydrothermal method, chemical vapor deposition (CVD), a precipitation method, a plasma method and the like. Due to the problems of high cost and low yield of the physical methods, the currently widely used method is the liquid phase reduction method in the chemical methods, i.e., a metal-containing salt solution or metal oxide is reduced to metal by a chemical reaction, such as a Chinese invention patent document CN104128616A provides a method for preparing metal particles.

However, metal particles currently required in production are generally spherical, but the proportion of particles of a desired shape to the total number of particles in its sample is very small, and the metal particles include particles of many other shapes, such as a lamella, a hexagon, a triangle, and a cube, and there are many problems, and some samples have a large particle size and wide size distribution, which limits their application in the field of microelectronics.

A Chinese invention patent document CN105436517B in the prior art discloses a preparation method for inducing the production of metal powder by using nanosized seed crystals, and after metal seed crystals are added, the problems that the surface roughness of metal powder is large and irregularity of metal powder is large are still present, resulting in metal powder with an angular polygonal appearance.

### SUMMARY

An object of the present invention is to overcome the shortcomings in the prior art to provide a metal particle as well as a preparation method therefor and use thereof.

To achieve the above object, the technical solutions adopted by the present invention are as follows:
in a first aspect, the present invention provides a metal particle, wherein holes are distributed at the center in the metal particle.

Distribution of the holes at the center in the metal particle is at least one of:
a mode a: a plurality of holes uniformly distributed at the center of the metal particle;
a mode b: a plurality of holes centrally distributed at the center of the metal particle;
a mode c: a plurality of holes dispersed at the center of the metal particle; and
a mode d: annular holes around the center of the metal particle.

As a preferred embodiment of the metal particle according to the present invention, the holes have a hole size of at least one of;
a type a: the holes uniformly distributed at the center of the metal particle have a hole size ranging from 0.1 nm to 50 nm; preferably, a hole size ranging from 5 nm to 50 nm; and further preferably, a hole size ranging from 9 nm to 30 nm;
a type b: the holes centrally distributed at the center of the metal particle have a hole size ranging from 0.1 nm to 80 nm; preferably, a hole size ranging from 2 nm to 80 nm; and preferably, a hole size ranging from 2.5 nm to 60 nm;
a type c: the holes dispersed at the center of the metal particle have a hole size ranging from 1 nm to 60 nm; preferably, a hole size ranging from 10 nm to 60 nm; and preferably, a hole size ranging from 14 nm to 45 nm; and
a type d: a diameter of the annular holes is not more than half a diameter of the metal particle; preferably, the annular holes have a diameter ranging from 0.1 μm to 1 μm; and further, the annular holes have a diameter ranging from 0.2 μm to 0.5 μm.

As a preferred embodiment of the metal particle according to the present invention, the metal is at least one of gold, silver, copper, and nickel.

As a preferred embodiment of the metal particle according to the present invention, the metal particle has a grain size ranging from 10 nm to 80 nm; and the metal particle has a sphericity ranging from 0.6 to 1. Preferably, the sphericity ranges from 0.8 to 0.95.

In a second aspect, the present invention provides a method for preparing the metal particle described above, including the steps of:
(1) preparing a polyol-seed crystal system: dispersing spherical or quasi-spherical nano-metal seed crystals in a polyol mixed solution;
(2) adding the polyol-seed crystal system to a dispersion liquid, then adding an oxidizing solution and a reducing solution, and carrying out a reaction under stirring; wherein the oxidizing solution includes a metal oxide or metal salt containing a metal source in the seed crystals; and
(3) adding a flocculant, and performing precipitation and separation to obtain the metal particle.

In the present invention, with the spherical or quasi-spherical nano-metal particles as the seed crystals, the spherical or quasi-spherical nano-metal seed crystals are dispersed in polyol in the polyol-seed crystal system, i.e., the seed crystals are coated with the polyol, and the seed crystals are dispersed; after the polyol-seed crystal system is added to the dispersion liquid, alcohol-water replacement is produced, forming a uniform nanobubble coating composed of spherical and/or elliptical nanobubbles on the surfaces of the seed crystals, and when the oxidizing solution and the reducing solution are added for a reaction, crystal grains are reduced and precipitated on the surfaces of the seed crystals under the induction of the seed crystals, and the nanobubbles are pressed, causing the nanobubbles to rupture, and a very strong shock wave is generated to cause crystal lattices to rupture to form cavities during the growth of metal crystals; and in view of different sizes of the seed crystals, the size and number of the coated nanobubbles are also different, so that cavities of different sizes and shapes are formed in the central regions of the metal crystals during the growth of the metal crystals, and the proportion of metal particles having different types of cavities is related to the particle size distribution of the spherical nano-metal seed crystals.

In addition, in the present invention, with the spherical or quasi-spherical nano-metal particles as the seed crystals, fine crystal grains are formed by clustering around the seed crystals through crystallization, and during the process of inducing grain growth, the two-dimensional effect generated at the crystal interface is more uniform, thereby forming metal particles with smaller crystal grains and higher sphericity; since the spherical or quasi-spherical seed crystals have a uniform grain boundary bonding force, the reaction is rapidly accelerated, promoting the cavity effect formed during the reaction, holes are formed in the central region in the metal particle during the reaction, and a shrinkage ratio of grains of the metal particle is more uniform and the shrinkage ratio is greater. Furthermore, the polyol-seed crystal system of the present invention promotes the formation of bubbles during the reaction, and there is an affinity of similar solvents between the polyol and the dispersion liquid, further promoting the dispersion of the seed crystals. The dispersion liquid disperses the resulting metal particles to prevent agglomeration of the metal particles during the reaction.

As a preferred embodiment of the method for preparing the metal particle according to the present invention, the metal is at least one of gold, silver, copper, and nickel.

As a preferred embodiment of the method for preparing the metal particle according to the present invention, in the step (1), the seed crystals have a particle size ranging from 1 nm to 100 nm. Preferably, the seed crystals have a particle size ranging from 1 nm to 70 nm. Further preferably, the seed crystals have a particle size ranging from 5 nm to 40 nm.

The seed crystals of this particle size are selected so that due to the presence of a plurality of small air bubbles in the reaction solution, a cavity effect is produced in a crystallization process of the metal particle during the reaction, forming holes in the metal particle; and for the cavity effect in the reaction process, with the increase of the particle size of the seed crystals within a limited range, the small air bubbles in the reaction solution form larger air bubbles in the metal particle, forming holes.

As a preferred embodiment of the method for preparing the metal particle according to the present invention, in the step (1), polyol in the polyol mixed solution ranges from 15% by volume to 95% by volume. Preferably, the polyol ranges from 50% by volume to 85% by volume, the balance being at least one of dispersants and/or surfactants of esters, ethers, ketones, ether esters, hydrocarbons, amines, and pyrrolidones; and preferably, at least one of polyvinylpyrrolidone, octylamine, and Tween.

As a preferred embodiment of the method for preparing the metal particle according to the present invention, in the step (1), the polyol is at least one of pentaerythritol, ethylene glycol, 1,2-propylene glycol, 1,4-butylene glycol, 1,6-hexanediol, neopentyl glycol, diethylene glycol, dipropylene glycol, and glycerol.

As a preferred embodiment of the method for preparing the metal particle according to the present invention, in the step (2), the stirring is performed at a rate ranging from 5 rpm to 1000 rpm. Preferably, the stirring is performed at a rate ranging from 50 rpm to 500 rpm.

As a preferred embodiment of the method for preparing the metal particle according to the present invention, in the step (2), the content of the metal seed crystals ranges from 0.0001% to 0.01% of a mass of a metal in the oxidizing solution. Preferably, the content of the metal seed crystals ranges from 0.0002% to 0.001% of the mass of the metal in the oxidizing solution.

As a preferred embodiment of the method for preparing the metal particle according to the present invention, in the step (2), the reaction temperature is from 10° C. to 90° C. Preferably, the reaction temperature is from 20° C. to 40° C.

As a preferred embodiment of the method for preparing the metal particle according to the present invention, in the step (2), the oxidizing solution has a pH ranging from 2.5 to 8.5. Preferably, the oxidizing solution has a pH ranging from 5 to 7.5.

As a preferred embodiment of the method for preparing the metal particle according to the present invention, in the step (2), the reducing solution includes at least one of reducing agents of hydrazines, amines, organic acids, alcohols, aldehydes, hydrides, salts of transition metals, pyrrolidones, and hydroxylamines.

Preferably, the hydrazines are selected from at least one of hydrazine, hydrazine hydrate, phenylhydrazine, and hydrazine sulfate; the amines are selected from at least one of dimethylaminoethanol, triethylamine, octylamine, and dimethylaminoborane; the organic acids are selected from at least one of citrate, ascorbic acid and a salt thereof, tartrate, gallic acid and a salt thereof, malate, malonic acid and a salt thereof, and formic acid; the alcohols are selected from at least one of methanol, ethanol, isopropanol, ethylene glycol, diethylene glycol, triethylene glycol, and tetraethylene glycol; the hydrides are selected from at least one of sodium borohydride, lithium borohydride, lithium triethylborohydride, lithium aluminum hydride, diisobutylaluminum hydride, tributyltin hydride, lithium tri-sec-butylborohydride, potassium tri-sec-butylborohydride, zinc borohydride, and sodium acetoxyborohydride; the salts of the transition metals are selected from iron sulfate and/or tin sulfate; the pyrrolidones are selected from at least one of polyvinylpyrrolidone, 1-vinylpyrrolidone, N-vinylpyrrolidone, and methylpyrrolidone; and the hydroxylamines are selected from hydroxylamine sulfate and/or hydroxylamine nitrate.

As a preferred embodiment of the method for preparing the metal particle according to the present invention, in the step (2), the reducing agent is added in an amount ranging from 0.1 equivalent to 7 equivalents based on a mass of a metal in the oxidizing solution being 1 equivalent. Preferably, the reducing agent is added in an amount ranging from 1 equivalent to 5 equivalents.

When the addition amount of the reducing agent is less than 0.1, unreduced metal may remain, and when the addition amount of the reducing agent exceeds 7, the reaction will be too fast, the condensed particles increase, and a final particle size is not uniform.

As a preferred embodiment of the method for preparing the metal particle according to the present invention, in the step (2), the dispersant is added in an amount of 0.1 to 5 times a mass of a metal oxide or metal salt in the oxidizing solution.

As a preferred embodiment of the method for preparing the metal particle according to the present invention, in the step (2), the dispersion liquid contains at least one of dispersants and/or surfactants of organic acids, esters, ethers, ketones, ether esters, alcohols, hydrocarbons, amines, and pyrrolidones.

Preferably, the dispersants are selected from at least one of a fatty acid salt, an alpha-sulfo fatty acid ester salt, alkylbenzene sulfonate, linear alkylbenzene sulfonate, alkyl sulfate, alkyl ether sulfate, triethanol alkyl sulfate, fatty acid ethanolamide, polyoxyethylene alkyl ether, polyoxyethylene alkylphenyl ether, sorbitol, sorbitan, an alkyltrimethylammonium salt, dialkyldimethylammonium chloride, alkylpyridinium chloride, alkylcarboxybetaine, sulfobetaine, lecithin, a formaldehyde condensate of naphthalene sulfonate, polystyrene sulfonate, polyacrylate, a copolymer salt of a vinyl compound and a carboxylic monomer, carboxymethylcellulose, polyvinyl alcohol, polypartial alkyl acrylate and/or polyalkylenepolyamine, polyethyleneimine and/or an aminoalkylmethacrylate copolymer, polyvinylpyrrolidone, 1-vinylpyrrolidone, N-vinylpyrrolidone, and methylpyrrolidone.

Preferably, the dispersants are selected from at least one of polyvinylpyrrolidone, octylamine, ethanol, polyethylene glycol, Tween, glycerol, and malic acid.

As a preferred embodiment of the method for preparing the metal particle according to the present invention, in the step (2), the oxidizing solution and/or the reducing solution may be pumped or pressed by compressed air or poured into the dispersion liquid, and the oxidizing solution and/or the reducing solution is added at a flow rate ranging from 1 mL/min to 1500 L/min; and the stirring is performed at a rate ranging from 50 rpm to 500 rpm.

Compared with the prior art, the flow rate range is greatly improved, the stirring reaction speed is fast, the reaction conditions are wider, the production capacity is increased, and large-scale production can be realized.

As a preferred embodiment of the method for preparing the metal particle according to the present invention, in the step (3), the flocculant is selected from fatty acids and/or a carboxylic acid compound.

Preferably, the fatty acids are at least one saturated fatty acid selected from caprylic acid, capric acid, lauric acid, myristic acid, palmitic acid, stearic acid, and arachidic acid, or at least one unsaturated fatty acid selected from oleic acid, linoleic acid, linolenic acid, and arachidonic acid and a salt thereof, and
the carboxylic acid compound is at least one of a compound having a carbon-carbon double bond (e.g., sorbic acid), a dihydroxy compound (e.g., adipic acid), and a dicarboxyl compound.

After the reaction, nanoparticles are flocculated by adding the flocculant to change a charge potential (ξ-potential) on the particles and the surfaces where the particles are bound to other particles, and precipitation and separation are then performed to obtain nano-metal particles.

In a third aspect, the present invention provides use of the metal particle described above in a photovoltaic cell and/or a semiconductor conductive adhesive.

Compared with the prior art, the beneficial effects of the present invention are as follows: The metal particle of the present invention has a high sphericity, holes distributed at the center therein, a low shrinkage ratio, and small grains (10-80 nm) therein, is suitable for use in silver paste of HJT (a heterojunction cell), and is applied to the fields of perc SP, step-by-step printing, etc. For example, when the metal particles having a high shrinkage ratio are applied to screen printing of a solar panel, a line width can be narrowed and the conversion efficiency can be increased by 0.05% to 0.1% when a front electrode of the solar panel is sintered at a high temperature.

According to the method for preparing the metal particle of the present invention, the spherical or quasi-spherical metal seed crystals are introduced to prepare the polyol-seed crystal system, so that the metal particle has a controllable particle size and degree of sphericity in a whole reduction process, metal particles in a metal oxide or metal salt solution containing a metal source in the seed crystals can be rapidly and stably reduced, and the shape of formed metal particles is guaranteed to spherical or quasi-spherical; and the particle sizes of the metal particles can be adjusted by means of the number and the sizes of the introduced spherical nano-metal seed crystals.

### BRIEF DESCRIPTION OF THE DRAWINGS

FIG. 1 is an electron micrograph (200K×) of spherical silver seed crystals used in the examples;

FIG. 2 is an electron micrograph (40K×) of spherical silver seed crystals used in the examples

FIG. 3 is an electron micrograph (20K×) of silver particles prepared in Example 1;

FIG. 4 is an electron micrograph (30K×) of the silver particles prepared in Example 1;

FIG. 5 is an X-ray diffraction (XRD) detection pattern of the silver particles prepared in Example 1;

FIG. 6 is an electron micrograph (10K×) of silver particles prepared in Example 2;

FIG. 7 is an electron micrograph of the silver particles prepared in Example 2 after cross-cutting;

FIG. 8 is an electron micrograph (10K×) of silver particles prepared in Example 3;

FIG. 9 is an electron micrograph of the silver particles prepared in Example 3 after cross-cutting;

FIG. 10 is an electron micrograph (10K×) of silver particles prepared in Example 4;

FIG. 11 is an electron micrograph of the silver particles prepared in Example 4 after cross-cutting;

FIG. 12 is an electron micrograph (20K×) of silver particles prepared in Example 5;

FIG. 13 is an electron micrograph of the silver particles prepared in Example 5 after cross-cutting;

FIG. 14 is a thermomechanical analysis (TMA) detection pattern of silver particles prepared in Examples 1-5; wherein a is a detection curve of the silver particles prepared in Example 1, b is a detection curve of the silver particles prepared in Example 3, c is a detection curve of the silver particles prepared in Example 4, d is a detection curve of the silver particles prepared in Example 2, and e is a detection curve of the silver particles prepared in Example 5;

FIG. 15 is an electron micrograph (150K×) of copper seed crystals used in Example 6;

FIG. 16 is an electron micrograph (100K×) of gold seed crystals used in Example 8;

FIG. 17 is an electron micrograph of silver seed crystals used in Comparative examples 1 and 2;

FIG. 18 is an electron micrograph (10K×) of silver particles prepared in Comparative example 1;

FIG. 19 is a thermomechanical analysis (TMA) detection pattern of the silver particles prepared in Comparative example 1;

FIG. 20 is an electron micrograph (10K×) of silver particles prepared in Comparative example 2; and

FIG. 21 is an X-ray diffraction (XRD) detection pattern of silver particles prepared in Comparative example 3.

### DETAILED DESCRIPTION

To better illustrate the objects, technical solutions and advantages of the present invention, the present invention will be further described below with reference to specific examples. It should be understood by those skilled in the art that the specific examples described herein are merely illustrative of the present invention, and are not intended to limit the present invention.

The test methods used in the examples are conventional methods unless otherwise specified; and the materials, reagents and the like used are commercially available unless otherwise specified. The metal particles may also be referred to simply as “particles” and are typically operated in a powder state, and may also be referred to as “metal particle powder” or referred to simply as “powder”. The D50 is a corresponding particle size when the cumulative particle size distribution percentage of a sample reaches 50%.

### Example 1

### (1) Preparation of an Oxidizing Solution

100 g of a silver nitrate solid or an equivalent amount of silver nitrate liquid was dissolved in 250 mL of deionized water, a pH was adjusted to 5, and the solution was kept at a constant temperature of 20° C.;

### (2) Preparation of a Reducing Solution

50 g of vitamin C was added to 250 mL of deionized water to prepare the reducing solution, and the solution was kept at a constant temperature of 20° C.;

### (3) Preparation of Dispersion Liquid

20 g of PVP was dissolved in 300 mL of deionized water to prepare the dispersion liquid, and well stirring was performed; and the solution was kept at a constant temperature of 20° C.;

### (4) Preparation of a Polyol-Seed Crystal System

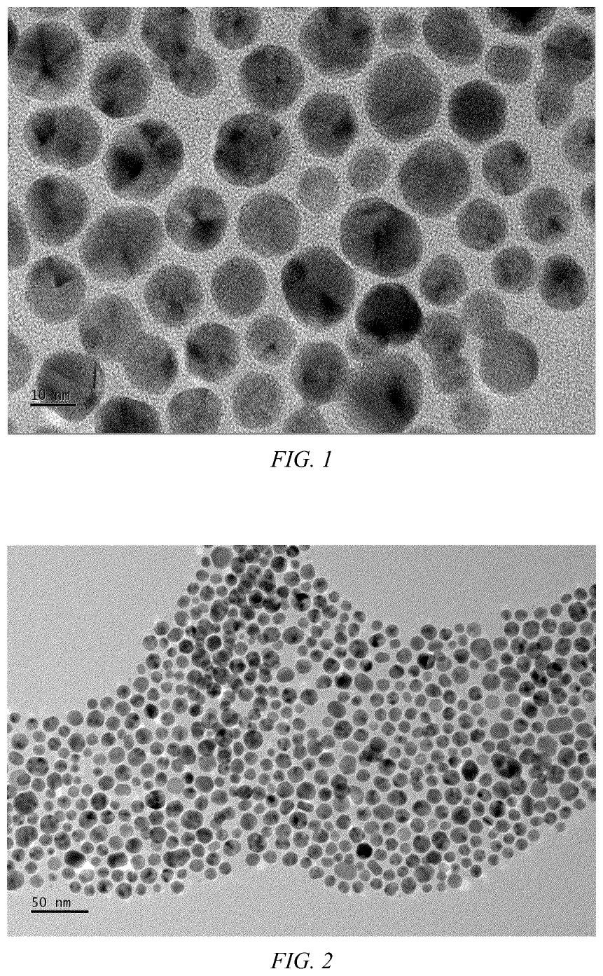

spherical nano-silver seed crystals were taken and dispersed in glycerol with a volume percentage of 80% (the balance being PVP), wherein the spherical nano-silver seed crystals have a particle size ranging from 5 nm to 40 nm, and a mass of the spherical nano-silver seed crystals was 0.001% of a mass of silver in the silver nitrate-containing solution, and the solution was kept at a constant temperature of 20° C.; wherein seed crystals magnified by an electron microscope are shown in FIG. 1 (200K×) and FIG. 2 (40K×); and

### (5) Preparation of Metal Particles

the dispersion liquid was pumped into a reactor in advance by using a metering pump, the polyol-seed crystal system was put into the reactor, and then the oxidizing solution and the reducing solution were simultaneously pumped into the reactor (a flow rate: 38 mL/Min); and a reduction reaction was carried out at a stirring rate of 50 rpm, and after completion of the reaction, 0.031 g of a flocculant stearic acid was added, and precipitation and separation were performed to obtain silver particle powder.

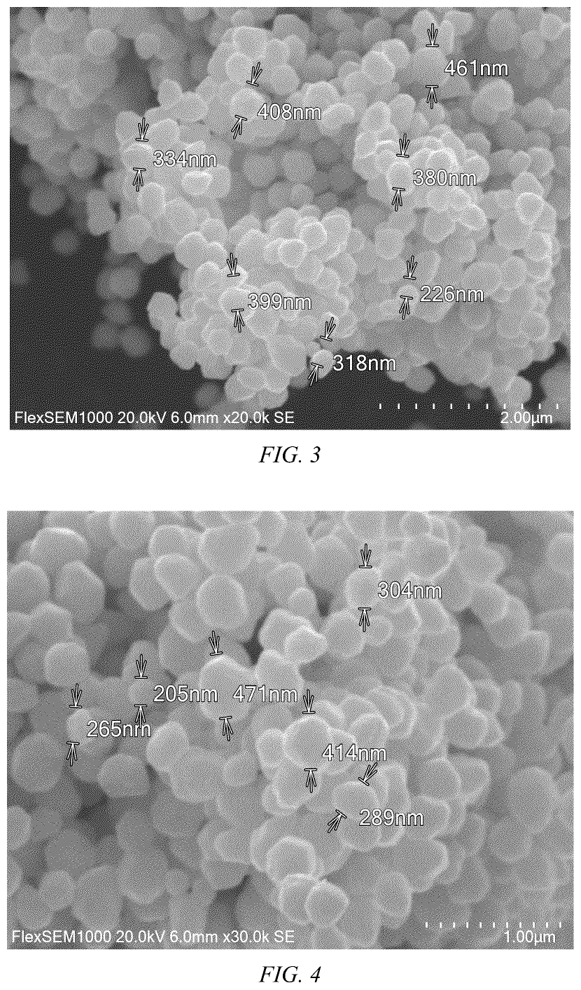

As shown in FIG. 3, silver particles are observed under an electron microscope at a magnification of 20K×, and the resulting silver particles have a high sphericity. As shown in FIG. 4, the silver particles are observed under an electron microscope at a magnification of 30K×, and it can be seen that that the silver particles have a D50 of about 400 nm, and the silver particles have a high sphericity. An average value of sphericity is calculated to be 0.89 according to a principle of a method in GB/T37406-2019.

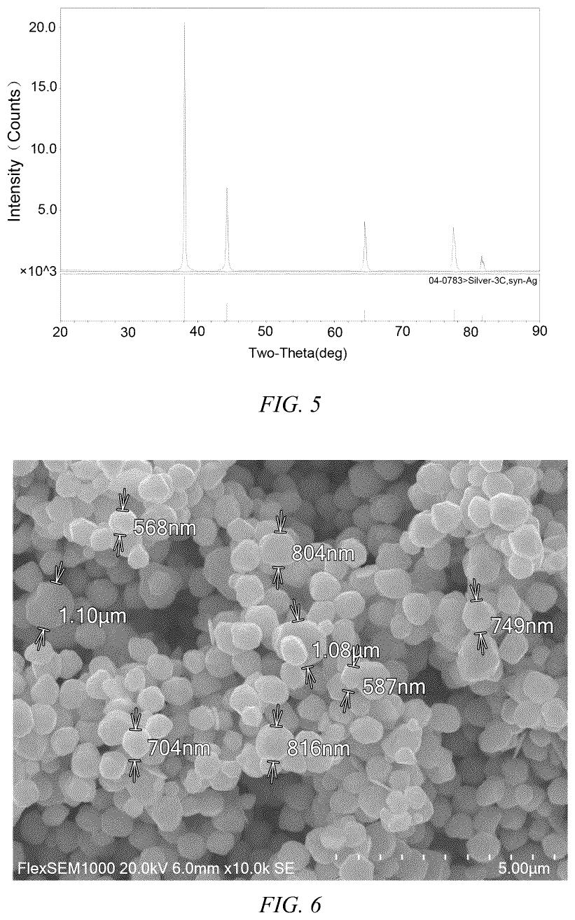

The obtained silver particle sample was detected by XRD (X-ray diffraction spectrometer model: Shimadzu XRD-6100, Japan), and as shown in FIG. 5, a measured value is 20561, a peak value is higher, indicating that a crystal form of the obtained silver particles is uniform, and a peak is sharper, indicating that the obtained silver particles are uniform in particle size and concentrated in distribution.

### Example 2

### (1) Preparation of an Oxidizing Solution

100 g of a silver nitrate solid or an equivalent amount of silver nitrate liquid was dissolved in 250 mL of deionized water, a pH was adjusted to 6.5, and the solution was kept at a constant temperature of 30° C.;

### (2) Preparation of a Reducing Solution

20 g of hydrazine hydrate was added to 250 mL of deionized water to prepare the reducing solution, and the solution was kept at a constant temperature of 30° C.;

### (3) Preparation of Dispersion Liquid

20 g of octylamine was dissolved in 300 mL of deionized water to prepare the dispersion liquid, and well stirring was performed; and the solution was kept at a constant temperature of 30° C.;

### (4) Preparation of a Polyol-Seed Crystal System

spherical nano-silver seed crystals were taken and dispersed in glycerol with a volume percentage of 65% (the balance being PVP), wherein the spherical nano-silver seed crystals have a particle size ranging from 5 nm to 40 nm, and a mass of the spherical nano-silver seed crystals was 0.0005% of a mass of silver in the silver nitrate-containing solution, and the solution was kept at a constant temperature of 30° C.; wherein seed crystals magnified by an electron microscope are shown in FIG. 1 (200K×) and FIG. 2 (40K×); and

### (5) Preparation of Metal Particles

the dispersion liquid was pumped into a reactor in advance by using a metering pump, the polyol-seed crystal system was put into the reactor, and then the oxidizing solution and the reducing solution were simultaneously pumped into the reactor (a flow rate: 38 mL/Min); and a reduction reaction was carried out at a stirring rate of 50 rpm, and after completion of the reaction, 0.05 g of a flocculant oleic acid was added, and precipitation and separation were performed to obtain silver particle powder.

A silver particle sample is observed under an electron microscope at a magnification of 10K×, and as shown in FIG. 6, the resulting silver particles have a high sphericity and rounded edges, and the sphericity is calculated to be 0.92 according to a principle of a method in GB/T37406-2019. Grains in the silver particles have a size ranging from 10 nm to 80 nm. Compared with Example 1, the number of the added seed crystals is reduced, and the particle size of the resulting silver particles also increases, and the silver particles have a D50 of about 600 nm.

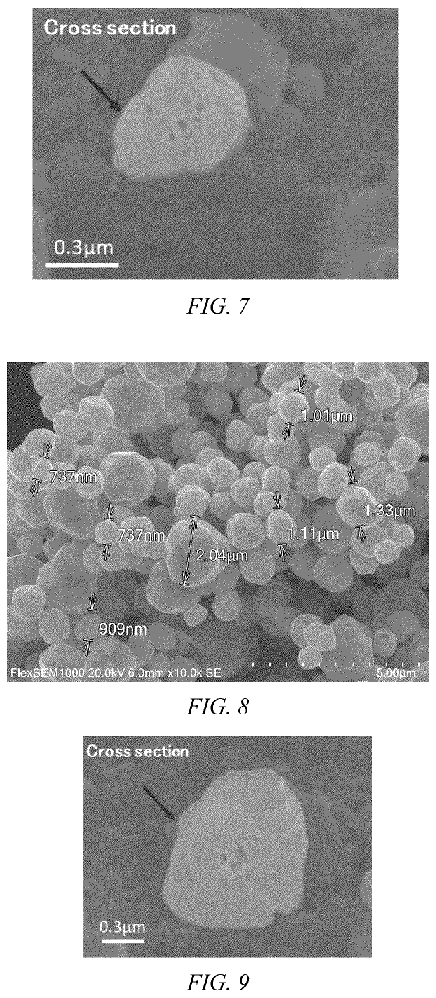

A method for cutting silver particles by gallium ions is adopted, and a cross section of the resulting silver particles is observed under an electron microscope, and three silver particles are randomly selected for cross-sectional observation. The samples are dispersed on a carbon slurry, and measured under ultra-high vacuum, as shown in FIG. 7, there are more holes in the silver particles, the holes are evenly distributed at the centers of the silver particles, and the holes have a size ranging from 9 nm to 29 nm; this is because the spherical or quasi-spherical seed crystals have a uniform grain boundary bonding force so that the catalytic reaction is rapidly accelerated, resulting in a cavity effect during the reaction, eventually forming holes in the metal particles. The silver particles with more holes uniformly distributed at the centers of the silver particles have a higher metal shrinkage ratio obtained by TMA, and can be applied to a wide range of technical fields of HIT silver paste, perc SP, step-by-step printing, etc.

### Example 3

### (1) Preparation of an Oxidizing Solution

100 g of a silver nitrate solid or an equivalent amount of silver nitrate liquid was dissolved in 250 mL of deionized water, a pH was adjusted to 6.8, and the solution was kept at a constant temperature of 40° C.;

### (2) Preparation of a Reducing Solution

12 g of sodium borohydride was added to 200 mL of deionized water having a pH of greater than 10 to prepare the reducing solution, and the solution was kept at a constant temperature of 40° C.;

### (3) Preparation of Dispersion Liquid

20 g of Tween was dissolved in 300 mL of deionized water to prepare the dispersion liquid, and well stirring was performed; and the solution was kept at a constant temperature of 30° C.;

### (4) Preparation of a Polyol-Seed Crystal System

spherical nano-silver seed crystals were taken and dispersed in ethylene glycol with a volume percentage of 65% (the balance being PVP), wherein the spherical nano-silver seed crystals have a particle size ranging from 10 nm to 40 nm, and a mass of the spherical nano-silver seed crystals was 0.00025% of a mass of silver in the silver nitrate-containing solution, and the solution was kept at a constant temperature of 40° C.; wherein the seed crystals were ACS1044 spherical nano-silver particles; and

### (5) Preparation of Metal Particles

the dispersion liquid was pumped into a reactor in advance by using a metering pump, the polyol-seed crystal system was put into the reactor, and then the oxidizing solution and the reducing solution were pumped into the reactor (a flow rate: 38 mL/Min); and a reduction reaction was carried out at a stirring rate of 350 rpm, and after completion of the reaction, 0.03 g of a flocculant adipic acid was added, and precipitation and separation were performed to obtain silver particle powder.

A silver particle sample is observed under an electron microscope at a magnification of 10K×, and as shown in FIG. 8, the resulting silver particles have a high sphericity, and the sphericity is calculated to be 0.88 according to a principle of a method in GB/T37406-2019.

Compared with Example 2, the number of the added seed crystals is reduced by half, and the particle size of the resulting silver particles becomes larger, and the silver particles have a D50 of about 1.2 microns.

A method for cutting silver particles by gallium ions is adopted, and a cross section of the resulting silver particles is observed under an electron microscope, and three silver particles are randomly selected for cross-sectional observation. The samples are dispersed on a carbon slurry, and measured under ultra-high vacuum. As shown in FIG. 9, there are a small number of larger holes in the silver particles. The holes are centrally distributed at the centers of the silver particles, and have a size ranging from 2.5 nm to 60 nm. A metal shrinkage ratio obtained by TMA of such silver particles is slightly lower than that of the silver particles with more holes uniformly distributed at the centers of the particles in Example 2.

### Example 4

### (1) Preparation of an Oxidizing Solution

250 kg of a silver nitrate solid or an equivalent amount of silver nitrate liquid was dissolved in 650 mL of deionized water, a pH was adjusted to 6.5, and the solution was kept at a constant temperature of 20° C.;

### (2) Preparation of a Reducing Solution

150 kg of ascorbic acid was added to 250 L of deionized water to prepare the reducing solution, and the solution was kept at a constant temperature of 20° C.;

### (3) Preparation of Dispersion Liquid

60 kg of polyethylene glycol was dissolved in 700 L of deionized water to prepare the dispersion liquid, and well stirring was performed; and the solution was kept at a constant temperature of 20° C.;

### (4) Preparation of a Polyol-Seed Crystal System

spherical nano-silver seed crystals were taken and dispersed in 1,2-propanediol with a volume percentage of 50% (the balance being PVP), wherein the spherical nano-silver seed crystals have a particle size ranging from 10 nm to 40 nm, and a mass of the spherical nano-silver seed crystals was 0.0002% of a mass of silver in the silver nitrate-containing solution, and the solution was kept at a constant temperature of 20° C.; wherein the seed crystals were ACS1044 spherical nano-silver particles; and

### (5) Preparation of Metal Particles

the dispersion liquid was pumped into a reactor in advance by using a metering pump, the polyol-seed crystal system was put into the reactor, and then the oxidizing solution and the reducing solution were pumped into the reactor (a flow rate: 40 L/Min to 60 L/Min); and a reduction reaction was carried out at a stirring rate ranging from 100 rpm to 200 rpm, and after completion of the reaction, 0.08 kg of a flocculant caprylic acid was added, and precipitation and separation were performed to obtain silver particle powder.

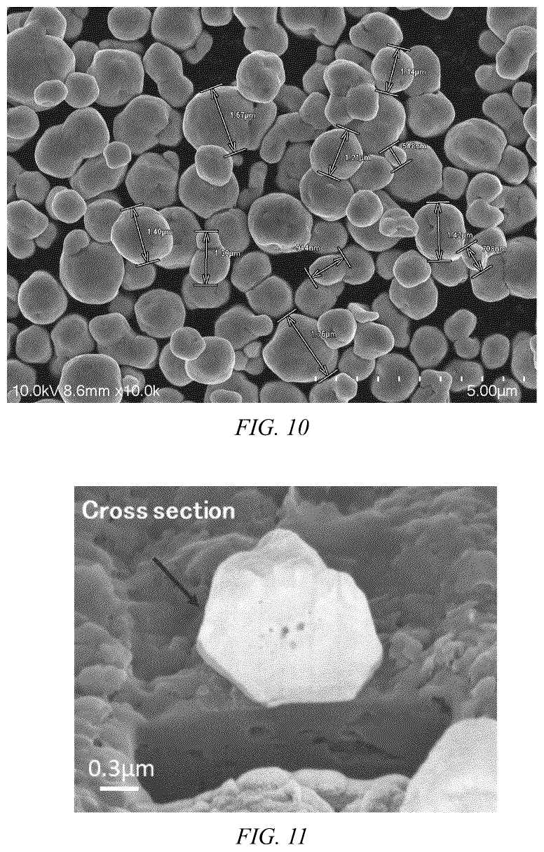

A silver particle sample is observed under an electron microscope at a magnification of 10K×, and as shown in FIG. 10, the resulting silver particles have a high sphericity, and the sphericity is calculated to be 0.87 according to a principle of a method in GB/T37406-2019. The resulting silver particles have a D50 of about 1.45 μm.

A method for cutting silver particles by gallium ions is adopted, and a cross section of the resulting silver particles is observed under an electron microscope, and three silver particles are randomly selected for cross-sectional observation. The samples are dispersed on a carbon slurry, and measured under ultra-high vacuum. As shown in FIG. 11, a small number of larger holes and fine holes are dispersed in the silver particles, and the holes are centrally distributed at the centers of the silver particles, and have a size ranging from 14 nm to 45 nm.

### Example 5

### (1) Preparation of an Oxidizing Solution

150 g of a silver nitrate solid or an equivalent amount of silver nitrate liquid was dissolved in 500 mL of deionized water, a pH was adjusted to 7.0, and the solution was kept at a constant temperature of 40° C.;

### (2) Preparation of a Reducing Solution

85 g of gallic acid was added to 500 mL of deionized water to prepare the reducing solution, and the solution was kept at a constant temperature of 40° C.;

### (3) Preparation of Dispersion Liquid

35 g of glycerol was dissolved in 350 mL of deionized water to prepare the dispersion liquid, and well stirring was performed; and the solution was kept at a constant temperature of 40° C.;

### (4) Preparation of a Polyol-Seed Crystal System

spherical nano-silver seed crystals were taken and dispersed in ethylene glycol with a volume percentage of 65% (the balance being PVP), wherein the spherical nano-silver seed crystals have a particle size ranging from 5 nm to 50 nm, and a mass of the spherical nano-silver seed crystals was 0.0004% of a mass of silver in the silver nitrate-containing solution, and the solution was kept at a constant temperature of 40° C.; and

### (5) Preparation of Metal Particles

the dispersion liquid was pumped into a reactor in advance by using a metering pump, the polyol-seed crystal system was put into the reactor, and then the oxidizing solution and the reducing solution were poured into the reactor; and a reduction reaction was carried out at a stirring rate ranging from 150 rpm to 350 rpm, and after completion of the reaction, 0.015 g of a flocculant oleic acid was added, and precipitation and separation were performed to obtain silver particle powder.

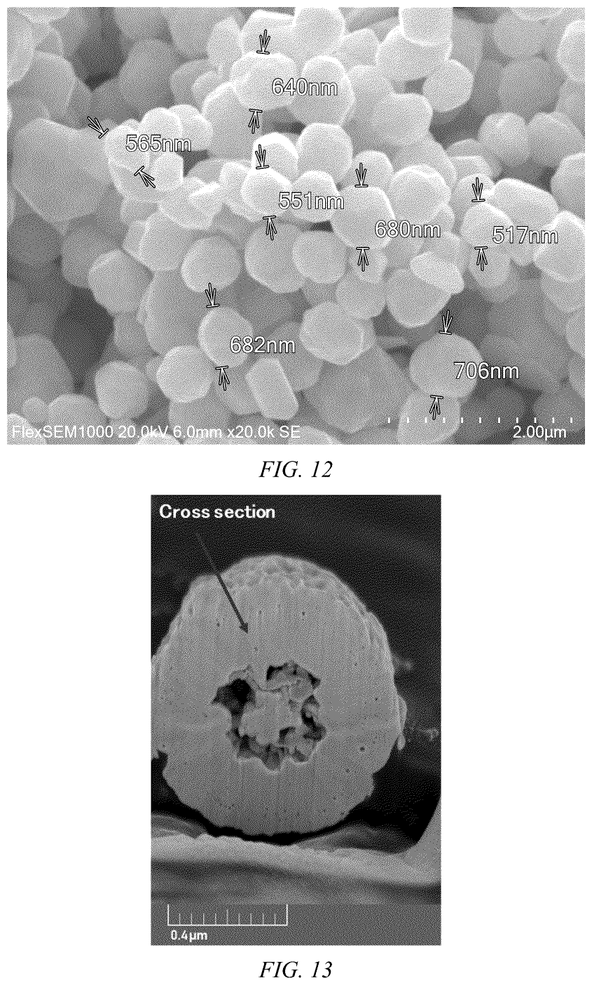

A silver particle sample is observed under an electron microscope at a magnification of 20K×, and as shown in FIG. 12, the resulting silver particles have a high sphericity, and the sphericity is calculated to be 0.86 according to a principle of a method in GB/T37406-2019. The obtained silver particles have a D50 of about 800 nm.

A method for cutting silver particles by gallium ions is adopted, and a cross section of the resulting silver particles is observed under an electron microscope, and three silver particles are randomly selected for cross-sectional observation. The samples are dispersed on a carbon slurry, and measured under ultra-high vacuum. As shown in FIG. 13, there are annular holes at the center in the silver particles, the size of the holes is no more than half a diameter of the metal particles, and the annular holes in this example have a diameter of 0.39 μm.

Due to the presence of a plurality of small air bubbles in the reaction solution, a cavity effect is produced in a crystallization process of the metal particles during the reaction, forming holes in the metal particles; and for the cavity effect in the reaction process, with the increase of the particle size of the seed crystals, the small air bubbles in the reaction solution form larger air bubbles in the metal particles.

In this example, spherical nano-silver seed crystals having a particle size ranging from 5 nm to 50 nm are used, and during the reaction, a portion of the metal particles are subjected to a two-stage reaction on the surfaces of smaller metal particles already formed, and an annular cavity is formed between the interface of the metal particles subjected to the original one-stage reaction and crystal grains formed by the two-stage reaction.

### Test Example

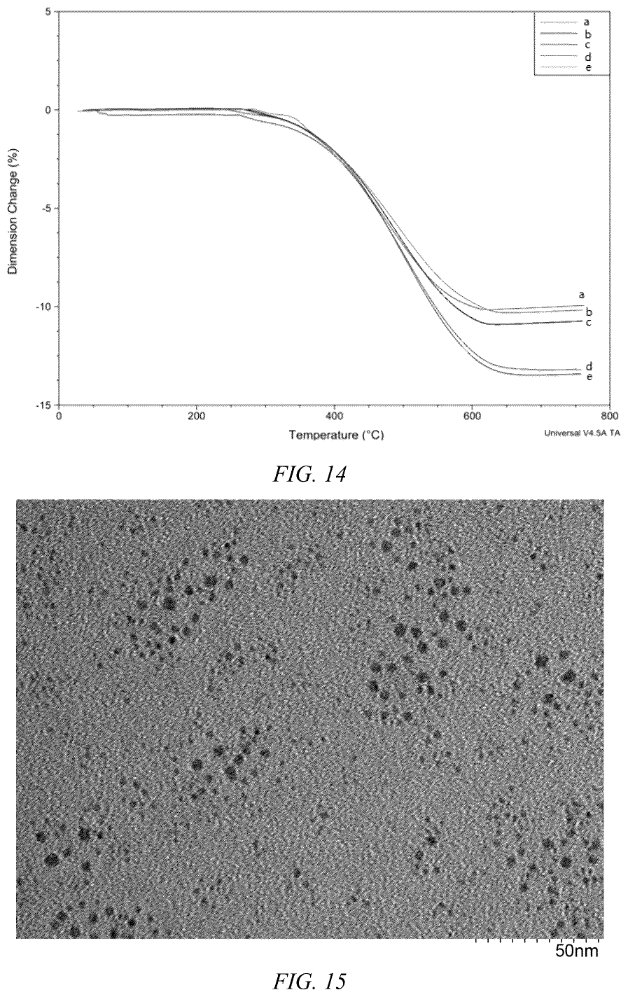

The silver particle powders prepared in Examples 1-5 were pressed into silver sheets, and a sintering shrinkage ratio was detected by using a thermomechanical analyzer TMA (USA TA model: Q400), and the results are shown in FIG. 14.

FIG. 14 is a thermomechanical analysis (TMA) detection pattern of silver particles prepared in Examples 1-5; wherein a is a detection curve of the silver particles prepared in Example 1, b is a detection curve of the silver particles prepared in Example 3, c is a detection curve of the silver particles prepared in Example 4, d is a detection curve of the silver particles prepared in Example 2, and e is a detection curve of the silver particles prepared in Example 5.

It can be seen that the silver particles prepared in Examples 2 and 5 have a shrinkage ratio of about 13.7%, and in Example 5, due to a specific structure of the annular holes formed in the central region of the particles, forming the annular holes can increase the sintering activity of the powder while contributing to improving the personalized requirements of a fine line printing design for different product formulations.

A shrinkage ratio of the silver particles prepared in Example 1 is about 9%, a shrinkage ratio of the silver particles prepared in Example 3 is about 10%, and a shrinkage ratio of the silver particles prepared in Example 4 is about 10.6%.

### Example 6

### (1) Preparation of an Oxidizing Solution

80 g of cupric oxide was dissolved in 600 mL of ammonium chloride, a pH was adjusted to 7.2, and the solution was kept at a constant temperature of 20° C.;

### (2) Preparation of a Reducing Solution

30 g of hydrazine hydrate was added to 600 mL of deionized water to prepare the reducing solution, and the solution was kept at a constant temperature of 20° C.;

### (3) Preparation of Dispersion Liquid

45 g of PVP was dissolved in 500 mL of deionized water to prepare the dispersion liquid, and well stirring was performed; and the solution was kept at a constant temperature of 20° C.;

### (4) Preparation of a Polyol-Seed Crystal System

Spherical nano-copper seed crystals were dispersed in glycerol with a volume percentage of 85% (the balance being octylamine), wherein the spherical nano-copper seed crystals have a particle size ranging from 5 nm to 10 nm, and a mass of the spherical nano-copper seed crystals was 0.0005% of a mass of copper in the copper-containing solution, and the solution was kept at a constant temperature of 20° C.; wherein the seed crystals were spherical nano-copper particles with a particle size of 5 nm, as shown in FIG. 15; and

### (5) Preparation of Metal Particles

the dispersion liquid was pumped into a reactor in advance by using a metering pump, the polyol-seed crystal system was put into the reactor, and then the oxidizing solution and the reducing solution were simultaneously pumped into the reactor (a flow rate: 50 mL/Min); and a reduction reaction was carried out at a stirring rate of 200 rpm, and after completion of the reaction, 0.03 g of a flocculant caprylic acid was added, and precipitation and separation were performed to obtain copper particle powder.

### Example 7

### (1) Preparation of an Oxidizing Solution

50 g of nickel sulfate was dissolved in 1600 mL of water, a pH was adjusted to 6.5, and the solution was kept at a constant temperature of 35° C.;

### (2) Preparation of a Reducing Solution

60 g of hydroxylamine sulfate was added to 1300 mL of deionized water to prepare the reducing solution, and the solution was kept at a constant temperature of 35° C.;

### (3) Preparation of Dispersion Liquid

50 g of sodium alkylbenzene sulfonate was dissolved in 300 mL of deionized water to prepare the dispersion liquid, and well stirring was performed; and the solution was kept at a constant temperature of 35° C.;

### (4) Preparation of a Polyol-Seed Crystal System

spherical nano-nickel seed crystals were dispersed in diethylene glycol with a volume percentage of 80% (the balance being octylamine), wherein the spherical nano-nickel seed crystals have a particle size ranging from 5 nm to 20 nm, and a mass of the spherical nano-nickel seed crystals was 0.0001% of a mass of nickel in the nickel-containing solution, and the solution was kept at a constant temperature of 35° C.; wherein the seed crystals were spherical nano-nickel particles; and

### (5) Preparation of Metal Particles

the dispersion liquid was pumped into a reactor in advance by using a metering pump, the polyol-seed crystal system was put into the reactor, and then the oxidizing solution and the reducing solution were pumped into the reactor (a flow rate: 30 mL/Min); and a reduction reaction was carried out at a stirring rate of 500 rpm, and after completion of the reaction, 0.095 g of a flocculant linoleic acid was added, and precipitation and separation were performed to obtain nickel particle powder.

### Example 8

### (1) Preparation of an Oxidizing Solution

A chloroauric acid (HAuCl₄) solution with a concentration of 24 mmol/L was prepared; and the solution was kept at a constant temperature ranging from 110° C. to 130° C.;

### (2) Preparation of a Reducing Solution

15 ml of ethylene glycol was the reducing solution; and the solution was kept at a constant temperature ranging from 110° C. to 130° C.;

### (3) Preparation of Dispersion Liquid

polyvinylpyrrolidone and polyethylene glycol were used as a double dispersant system in a mass ratio of PVP to PEG ranging from 1:9 to 3:7; and the solution was kept at a constant temperature ranging from 110° C. to 130° C.;

### (4) Preparation of a Polyol-Seed Crystal System

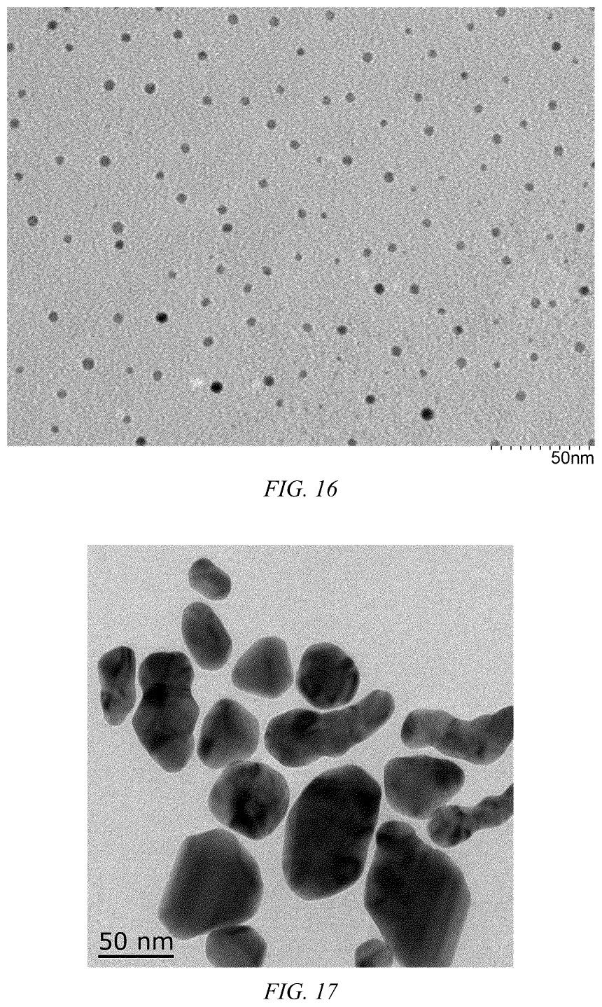

spherical nano-gold seed crystals were taken and dispersed in glycerol with a volume percentage of 85% (the balance being PVP), wherein the spherical nano-gold seed crystals have a particle size ranging from 5 nm to 50 nm, and a mass of the spherical nano-gold seed crystals was 0.0001% of a mass of gold in the chloroauric acid-containing solution; wherein the seed crystals are shown in FIG. 16; and

### (5) Preparation of Metal Particles

the temperature of a thermostatic reaction was set, the temperature of an oil bath pot was set to range from 110° C. to 130° C., the dispersion liquid was added to a reaction vessel, the polyol-seed crystal system was then added while stirring, then 15 ml of ethylene glycol was added, and 10 ml of the HAuCl₄ oxidizing solution having a concentration of 24 mmol/L was added dropwise into the reaction vessel in batches by using a dropper, the thermostatic reaction was carried out to make the mixture completely reacted, cooling was performed to room temperature, 0.0003 g of a flocculant was added, and precipitation and separation were performed to obtain gold particle powder.

### Comparative Example 1

### (1) Preparation of an Oxidizing Solution

100 g of a silver nitrate solid or an equivalent amount of silver nitrate liquid was dissolved in 250 mL of deionized water, a pH was adjusted to 7.5, and the solution was kept at a constant temperature of 30° C.;

### (2) Preparation of a Reducing Solution

50 g of vitamin C was added to 250 mL of deionized water to prepare the reducing solution, and the solution was kept at a constant temperature of 29° C.;

### (3) Preparation of Dispersion Liquid

20 g of PVP was dissolved in 250 mL of deionized water to prepare the dispersion liquid, and well stirring was performed; and seed crystals (40-50 nm) of irregularly shaped silver nanoparticles were added, wherein a mass of the added nano-silver seed crystals was 0.001% of a mass of silver in the silver nitrate solution, and the solution was kept at a constant temperature of 30° C.; wherein the seed crystals were G5 nano-silver particles, as shown in FIG. 17; and

### (4) Preparation of Metal Particles

the dispersion liquid was pumped into a reactor in advance by using a metering pump, and then the oxidizing solution and the reducing solution were pumped into the reactor (a flow rate: 50 mL/Min); and a reduction reaction was carried out at a stirring rate of 300 rpm, and after completion of the reaction, 0.30 g of a flocculant oleic acid was added, and precipitation and separation were performed to obtain silver particle powder.

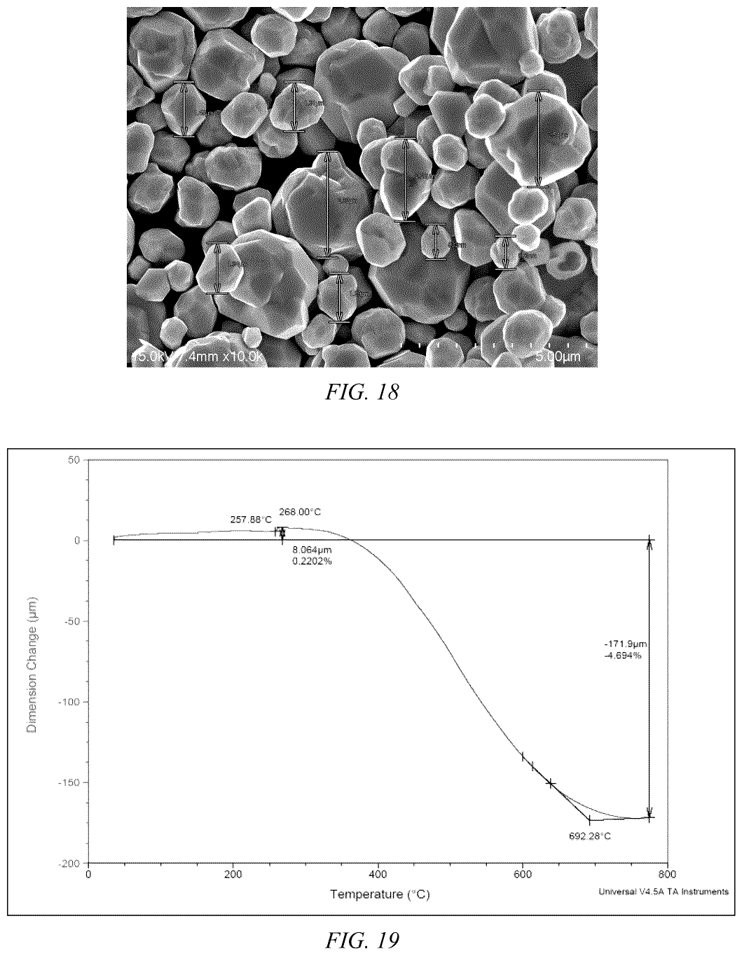

The silver particles are observed under an electron microscope at a magnification of 10K×, as shown in FIG. 18; and the resulting silver particles have a D50 ranging from 1.2 μm to 1.5 μm.

The prepared silver particle powder was pressed into silver sheets, and a sintering shrinkage ratio was detected by a thermomechanical analyzer TMA (USA TA model: Q400), and due to a solid structure at the centers of the particles, thermal loss is low, and as shown in FIG. 19, the shrinkage ratio is 4.694%.

### Comparative Example 2

### (1) Preparation of an Oxidizing Solution

100 g of a silver nitrate solid or an equivalent amount of silver nitrate liquid was dissolved in 250 mL of deionized water, a pH was adjusted to 7.0, and the solution was kept at a constant temperature of 30° C.;

### (2) Preparation of a Reducing Solution

50 g of vitamin C was added to 250 mL of deionized water to prepare the reducing solution, and the solution was kept at a constant temperature of 30° C.;

### (3) Preparation of Dispersion Liquid

20 g of PVP was dissolved in 300 mL of deionized water to prepare the dispersion liquid, and well stirring was performed; and seed crystals (40-50 nm) of irregularly shaped silver nanoparticles were added, wherein a mass of the added nano-silver seed crystals was 0.0005% of a mass of silver in the silver nitrate solution, and the solution was kept at a constant temperature of 30° C.; wherein the seed crystals were nano-silver seed crystal particles; and have a poor sphericity, sharp edges and an irregular shape, as shown in FIG. 17; and

### (4) Preparation of Metal Particles

the dispersion liquid was pumped into a reactor in advance by using a metering pump, and then the oxidizing solution and the reducing solution were pumped into the reactor (a flow rate: 50 mL/Min); and a reduction reaction was carried out at a stirring rate of 300 rpm, and after completion of the reaction, 0.033 g of a flocculant linoleic acid was added, and precipitation and separation were performed to obtain silver particle powder.

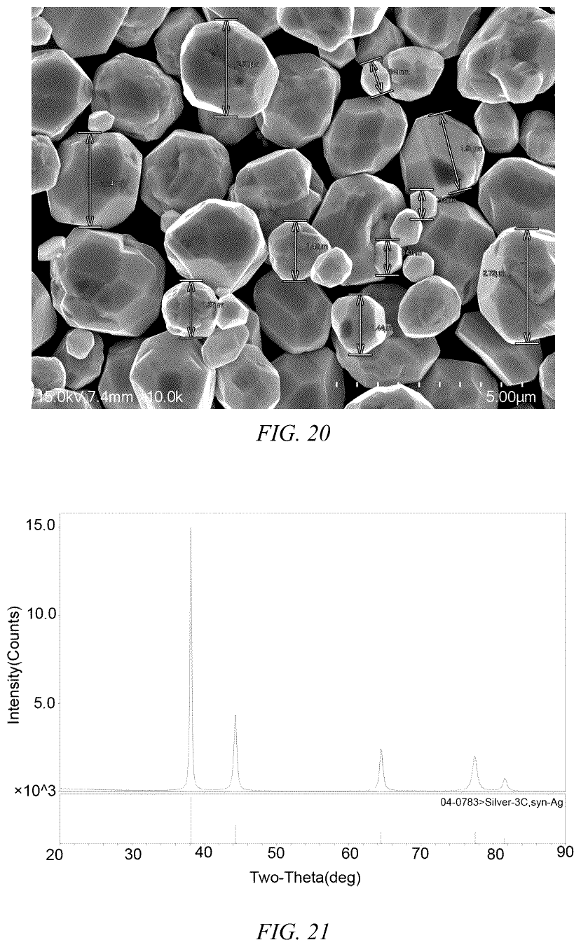

A silver particle sample is observed under an electron microscope at a magnification of 10K×, as shown in FIG. 20; and the resulting silver particles have a D50 ranging from 2.0 μm to 2.5 m, and have a poor sphericity, sharp edges and an irregular shape.

### Comparative Example 3

Silver particles were prepared by using a method in the invention patent document CN105436517B, and the obtained silver particles were detected by XRD (X-ray diffraction spectrometer model: Shimadzu XRD-6100, Japan), and as shown in FIG. 21, a measured value is 15046, a peak value is lower, indicating that a crystal form of the obtained silver particles is not uniform, and a peak is not sharp, indicating that the obtained silver particles are not uniform.

It should be noted that the above examples are only used to illustrate the technical solutions of the present invention, and are not intended to limit the protection scope of the present invention, although the present invention has been described in detail with reference to the preferred examples, it will be understood by those of ordinary skill in the art that modifications or equivalent replacements may be made to the technical solutions of the present invention without departing from the essence and scope of the present invention.

1. A metal particle, characterized in that holes are distributed at the center in the metal particle; and distribution of the holes at the center in the metal particle is at least one of:
a mode a: a plurality of holes uniformly distributed at the center of the metal particle;
a mode b: a plurality of holes centrally distributed at the center of the metal particle;
a mode c: a plurality of holes dispersed at the center of the metal particle; and
a mode d: annular holes around the center of the metal particle.

2. The metal particle according to claim 1, characterized in that the holes have a hole size of at least one of;
a type a: the holes uniformly distributed at the center of the metal particle have a hole size ranging from 0.1 nm to 50 nm;
a type b: the holes centrally distributed at the center of the metal particle have a hole size ranging from 0.1 nm to 80 nm;
a type c: the holes dispersed at the center of the metal particle have a hole size ranging from 1 nm to 60 nm; and
a type d: a diameter of the annular holes is not more than half a diameter of the metal particle.

3. The metal particle according to claim 1, characterized in that the metal is at least one of gold, silver, copper, and nickel.

4. The metal particle according to claim 1, characterized in that the metal particle has a grain size ranging from 10 nm to 80 nm; and the metal particle has a sphericity ranging from 0.6 to 1.

5. A method for preparing a metal particle, characterized by comprising the steps of:
(1) preparing a polyol-seed crystal system: dispersing spherical or quasi-spherical nano-metal seed crystals in a polyol mixed solution;
(2) adding the polyol-seed crystal system to a dispersion liquid, then adding an oxidizing solution and a reducing solution, and carrying out a reaction under stirring; wherein the oxidizing solution comprises a metal oxide or metal salt containing a metal source in the seed crystals; and
(3) adding a flocculant, and performing precipitation and separation to obtain the metal particle.

6. The method for preparing the metal particle according to claim 5, characterized in that the metal is at least one of gold, silver, copper, and nickel.

7. The method for preparing the metal particle according to claim 5, characterized in that in the step (1), the seed crystals have a particle size ranging from 1 nm to 100 nm.

8. The method for preparing the metal particle according to claim 5, characterized in that in the step (1), polyol in the polyol mixed solution ranges from 15% by volume to 95% by volume.

9. The method for preparing the metal particle according to claim 5, characterized in that in the step (1), the polyol is at least one of pentaerythritol, ethylene glycol, 1,2-propylene glycol, 1,4-butylene glycol, 1,6-hexanediol, neopentyl glycol, diethylene glycol, dipropylene glycol, and glycerol.

10. The method for preparing the metal particle according to claim 5, characterized in that in the step (2), the content of the metal seed crystals ranges from 0.0001% to 0.01% of a mass of a metal in the oxidizing solution.

11. The method for preparing the metal particle according to claim 5, characterized in that in the step (2), the reducing solution comprises at least one of reducing agents of hydrazines, amines, organic acids, alcohols, aldehydes, hydrides, salts of transition metals, pyrrolidones, and hydroxylamines.

12. The method for preparing the metal particle according to claim 5, characterized in that in the step (2), the dispersion liquid contains at least one of dispersants and/or surfactants of organic acids, esters, ethers, ketones, ether esters, alcohols, hydrocarbons, amines, and pyrrolidones.

13. The method for preparing the metal particle according to claim 12, characterized in that the dispersants are selected from at least one of a fatty acid salt, an alpha-sulfo fatty acid ester salt, alkylbenzene sulfonate, linear alkylbenzene sulfonate, alkyl sulfate, alkyl ether sulfate, triethanol alkyl sulfate, fatty acid ethanolamide, polyoxyethylene alkyl ether, polyoxyethylene alkylphenyl ether, sorbitol, sorbitan, an alkyltrimethylammonium salt, dialkyldimethylammonium chloride, alkylpyridinium chloride, alkylcarboxybetaine, sulfobetaine, lecithin, a formaldehyde condensate of naphthalene sulfonate, polystyrene sulfonate, polyacrylate, a copolymer salt of a vinyl compound and a carboxylic monomer, carboxymethylcellulose, polyvinyl alcohol, polypartial alkyl acrylate and/or polyalkylenepolyamine, polyethyleneimine and/or an aminoalkylmethacrylate copolymer, polyvinylpyrrolidone, 1-vinylpyrrolidone, N-vinylpyrrolidone, and methylpyrrolidone.

14. The method for preparing the metal particle according to claim 12, characterized in that the dispersants are selected from at least one of polyvinylpyrrolidone, octylamine, ethanol, polyethylene glycol, Tween, glycerol, and malic acid.

15. The method for preparing the metal particle according to claim 5, characterized in that in the step (3), the flocculant is selected from fatty acids and/or a carboxylic acid compound; wherein
the fatty acids are at least one saturated fatty acid selected from caprylic acid, capric acid, lauric acid, myristic acid, palmitic acid, stearic acid, and arachidic acid, or
at least one unsaturated fatty acid selected from oleic acid, linoleic acid, linolenic acid, and arachidonic acid and a salt thereof; and
the carboxylic acid compound is at least one of a compound having a carbon-carbon double bond, a dihydroxy compound, and a dicarboxyl compound.

16. Use of the metal particle according to claim 1 in a photovoltaic cell and/or a semiconductor conductive adhesive.

17. The method for preparing the metal particle according to claim 5, characterized in that in the step (1), polyol in the polyol mixed solution ranges from 50% by volume to 85% by volume.

18. The method for preparing the metal particle according to claim 8, characterized in that in the polyol mixed solution the balance is at least one of dispersants and/or surfactants of esters, ethers, ketones, ether esters, hydrocarbons, amines, and pyrrolidones.

19. The method for preparing the metal particle according to claim 17, characterized in that in the polyol mixed solution the balance is at least one of dispersants and/or surfactants of esters, ethers, ketones, ether esters, hydrocarbons, amines, and pyrrolidones.
